(19) United States
(12) Patent Application Publication
(10) Pub. No.: US 2015/0017456 A1
(43) Pub. Date: Jan. 15, 2015

(54) Reducing voids caused by trapped acid on a dielectric surface

(71) Applicant: Intermolecular Inc., San Jose, CA (US)

(72) Inventors: Anh Duong, Fremont, CA (US); Clemens Fitz, Dresden (DE)

(21) Appl. No.: 13/941,841

(22) Filed: Jul. 15, 2013

(51) Int. Cl. H01L 21/3105; H01L 21/66

(52) U.S. Cl. CPC H01L 21/3105; H01L 22/20
USPC 428/450; 438/476; 438/7

(57) ABSTRACT

When an etchant for metal (e.g., HF) reaches an underlying silicon oxide layer, it may form silanol bonds or other hydrogen bonds that resist rinsing, so that some etchant remains to be trapped under the next deposited layer. Trapped etchant can create voids that eventually degrade the performance of the oxide layer. Exposing the surface to a liquid solution or gaseous precursor containing silane seals the defects without causing an overall thickness change. The silane reacts at sites with silanol (or other hydrogen) bonds, breaking the bonds and replacing the hydrogen with silicon, but does not react in the absence of a hydrogen bond.

### BACKGROUND

Related fields include semiconductor fabrication; in particular, the reduction of voids caused by trapped etchants.

Hydrofluoric acid (HF) is used in semiconductor manufacturing to etch metal layers. One example is the etching of trenches in a metal layer to form metal gates. Another example is the removal of excess metal after doping-by-annealing: A layer of a dopant metal (e.g., Ni or Pt) is deposited on a semiconductor in a desired pattern; the entire structure is annealed at a temperature that causes the dopant metal to diffuse into the semiconductor under the patterned metal; then the remaining excess metal is removed.

Occasionally, the HF may etch past the metal being removed and into the underlying dielectric (e.g., the interlayer dielectric between metal gates), where it carves out hollows deeper than the intended trench bottoms between the features that are not selected for etching (e.g., features that are masked). After a rinse step intended to remove all the HF, some HF may remain on the dielectric. At the macroscopic level, the recessed spaces (especially any pre-existing voids created by a previous process) can be difficult to flush out completely. Moreover, at the molecular level, HF may form silanol (Si—O—H) bonds on the dielectric surface, trapping the HF at a molecular level. The dielectric film can be SiO2 or SiN. HF breaks the Si—O—Si or Si—N—Si bonds and forms Si-O-H instead.

When the dielectric is overcoated with the next material, bonded and otherwise unremoved HF is trapped. The trapped HF continues to etch the dielectric, creating voids that can detract from the performance, reliability, and lifetime of the device. For example, voids in an insulating dielectric may be filled with conductive material, such as a metal, either by inadvertent deposition (for an open void on the surface) or by diffusion (which can fill either open voids or completely enclosed voids). The voids filled with conductive material can form an unwanted current path through the insulator, resulting in a short.

Therefore, a need exists for a way to mitigate the effects of HF trapped on a dielectric surface; to prevent it from creating or enlarging voids.

Summary

The following summary presents some concepts in a simplified form as an introduction to the detailed description that follows. It does not necessarily identify key or critical elements and is not intended to reflect a scope of invention.

Defects are mitigated on a dielectric surface after the etching of an overlying metal layer with HF. The surface is rinsed with a solution that includes deionized water. The surface is then exposed to a material that includes silane. The silane seals defects on the surface by reacting with any silanol bonds and replacing the Si—O—H bond with Si—O—Si, a relatively stable silicon oxide bond that does not cause void formation after being trapped under the next applied layer.

The silane may be part of a liquid solution and the substrate may be exposed by spin-coating. The solution may be aqueous, may include an organic solvent, or may include a polymer or polymer precursor. Alternatively, the silane may be a gaseous precursor and the substrate may be exposed by chemical vapor deposition (CVD) or atomic layer deposition (ALD). Examples of suitable defect-sealing materials include, but are not limited to, 1,1,3,3-tetraethoxyl-1,3-dimethyl disiloxane, tetraethoxysilane (TEOS), and other alkyl silanes. The concentration of these solutions can range from 1% to 10% and can be deposited at room temperature for 30 sec to 5 min and then annealed at higher temperatures, such as 50-200 C for 30 sec to 5 min to form the Si—O—Si bond.

In some embodiments, the silane reacts only with Si—O—H or other unwanted bonds and does not react elsewhere on the dielectric surface. Thus, some embodiments of the defect-sealing process do not significantly increase an overall thickness of the dielectric.

A thin-film stack fabricated by these methods may include a dielectric layer from which an overlying metal layer has been removed. The top surface of the dielectric includes a defect zone, including hydrogen-bond defects. At least some of the defects are sealed by creating new silicon bonds to replace the hydrogen bonds.

Thin-film stacks may be fabricated by depositing an interlayer dielectric on a substrate; depositing a semiconductor over the interlayer dielectric; depositing a hard mask over the semiconductor; removing parts of the hard mask and underlying parts of the semiconductor to expose parts of the interlayer dielectric; depositing a metal-doped conformal layer; diffusing the metal dopant into the interlayer dielectric, the semiconductor, or the hard mask; etching part of the metal layer to expose the interlayer dielectric, semiconductor, or hard mask; rinsing the structure to remove the etchant; and exposing the structure to a silane-containing material that breaks hydrogen bonds on the exposed surface and replaces the hydrogen with silicon.

### BRIEF DESCRIPTION OF DRAWINGS

FIGS. 1A-1E conceptually illustrate the development of a defect zone.

FIGS. 2A and 2B conceptually illustrate defect sealing.

FIG. 3 is a flowchart of a process for defect sealing.

### DETAILED DESCRIPTION OF EXAMPLE EMBODIMENTS

The fabrication of semiconductor devices involves many complex and varied processes. To avoid obscuring the disclosure, we describe only a few.

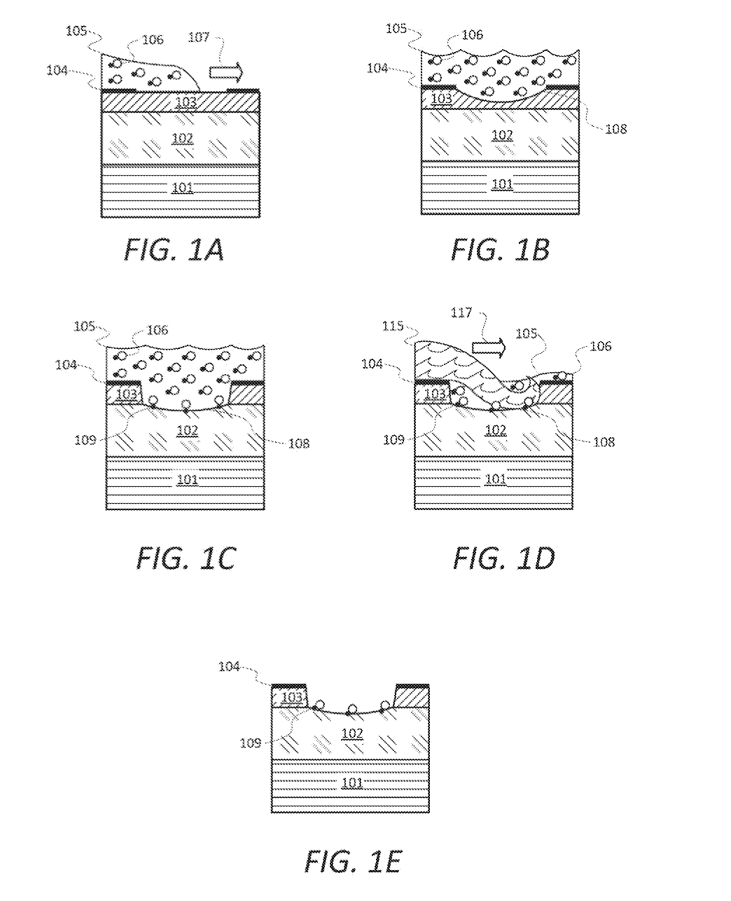

FIGS. 1A-1E conceptually illustrate the development of a defect zone in a dielectric resulting from trapped HF. On a substrate 101 (which may include many existing processed layers and structures) a dielectric layer 102 has been formed, and a metal layer 103 has been formed over dielectric layer 102. A mask 104 has been applied over metal layer 103 to protect some parts of the metal layer.

In FIG. 1A, the structure is exposed to a treatment solution 105 containing HF molecules 106. The process illustrated here is etching, but similar chemicals and exposure techniques are also used for cleaning and other processes. The exposure is represented here by a “wave” of solution 105 flowing in direction 107, but any suitable method of exposure to an HF solution may be used. Examples of HF concentration are 10:1, 50:1 or 100:1.

In FIG. 1B, HF solution 105 has begun to etch a trench 108 in a part of metal layer 103 that is not shielded by mask 104. Often, the goal is to remove all the metal from unmasked areas, so the process does not stop here.

In FIG. 1C, trench 108 has gone through metal layer 103 and the solution has begun etching dielectric layer 102. Some of the HF molecules 106 attach themselves to the surface of dielectric 102 by silanol bonds 109.

In FIG. 1D, a rinse solution 115 (commonly de-ionized water) represented by a wave traveling in direction 117, is introduced with the intent of clearing all the HF from the substrate. Unfortunately, some corners and bottoms of narrow, deep trenches 108 are difficult to flush out completely, and some of the silanol bonds 109 may be too strong for fluid pressure from rinse solution 115 to overcome.

In FIG. 1E, the rinse is finished and the structure is dried (e.g., in a nitrogen gas, with or without heating). There is still some HF trapped on the dielectric 102, either adhered by silanol bonds or left behind by an incomplete rinse of the trench. If not removed, these bonded molecules will continue attacking the dielectric to create or enlarge voids.

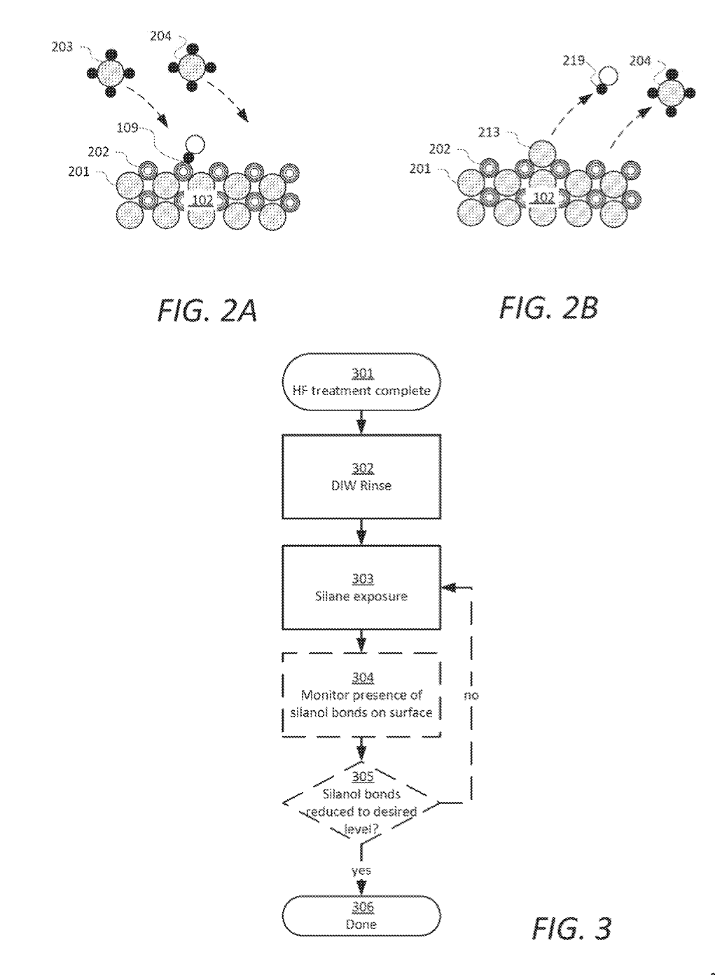

FIGS. 2A and 2B conceptually illustrate defect sealing. The surface of dielectric 102 is magnified to show a simplified representation of its molecular scale. The illustrated structure is not intended to represent any particular lattice, but a generalized composition of silicon 201 and oxygen 202. In FIG. 2A, an HF molecule is attached to the surface of dielectric 102 by a silanol bond 109. Silane molecules 203 and 204 are incoming, about to impinge on the dielectric surface 102.

In FIG. 2B, silane molecule 203 has broken silanol bond 109, freeing HF molecule 219 to be rinsed away or otherwise disposed of and inserting its own silicon atom 213 in place of the HF. The former silanol bond has become a more stable, inert silicon oxide bond that will not cause a void to develop or enlarge. Silane molecule 204, by contrast, did not find a reactive site (silanol or other unwanted hydrogen bond) when encountering the surface of dielectric 102. Because nothing caused it to react, it did not attach itself to dielectric 102. Thus, where a thicker silicon-based dielectric film is not wanted, none will be created; the reaction affects isolated sites here and there, and need add no more than a monolayer.

To determine whether only the silanol or other unwanted hydrogen bonds are reacting, Fourier transform infrared spectroscopy (FTIR) can be used to monitor the Si—O—H peak and Si—O—Si peak before and after the treatment. Contact angle measurement can also be used to measure the surface hydrophilicity and hydrophobicity of the SiO₂ before and after the treatment using water. Si—O—H is very hydrophilic, thus tends to have a low contact angle, while the SiO₂ is more hydrophobic, thus tends to have a higher contact angle.

FIG. 3 is a flowchart of a process for defect sealing. Once the HF treatment 301, which may be etching, cleaning, or any type of treatment where HF may form silanol bonds with a dielectric layer) is complete, the entire structure is rinsed 302 with de-ionized water (DIW) or another suitable rinse agent to remove as much of the HF as possible. The structure is then exposed 303 to silane to cleave any remaining silanol bonds and replace them with SiO bonds (or, in some embodiments, SiN or SiON bonds).

The exposure to silane can be done in any of several different ways. A gaseous silane precursor may be introduced in a CVD or ALD process chamber. The silanes can be heated in a reservoir near the structure or evaporated from a reservoir by vacuum. These processes are often done at ambient pressures between about 5 Torr and about 1 atmosphere and temperatures near 100 C. Silane can also be refluxed from a toluene solution to vaporize by inherent partial pressure. If needed, the substrate may be heated to about 50-150 C to promote reaction. Precursors include cyclic azasilanes, amine functional silanes, or other silanes with or without catalysts (e.g., amine catalysts). Specific examples include, but are not limited to, disilane (Si₂H₆), trisilane (Si₃H₈), neopentasilane (Si₅H₁₂, “NPS”), dichlorosilane (SiCl₂H₂, “DCS”), tris(dimethylamino)silane (C₆H₁₉N₃Si), and 2,4,6,8-tetramethylcyclotetrasiloxane (C₄H₁₆O₄Si₄). Some monolayer deposition processes favor dry aprotic conditions.

Alternatively, the exposure to silane may be a wet process (e.g., on a spin-coating apparatus) using a solution of a silane source in water or an organic solvent. The source of silane in the solution may be tetraethoxysilane (“TEOS”), 1,1,3,3-tetraethoxyl-1,3-dimethyl disiloxane, or any other suitable composition. Organic solvents may be preferable to water if the structure being treated contains hygroscopic substances and a hygroscopic reaction is undesired. The organic solvent may include a polymer precursor such as ethylene glycol, propylene carbonate (C₄H₆O₃, “PC”), or dimethyl sulfoxide (“DMSO”).

In some embodiments, the silane reaction is intended to be confined to sites with silanol bonds. Measures ordinarily used to promote silane reactivity when depositing a silicon-based film (heating or charging the substrate, introducing a plasma, and the like) may be abbreviated or omitted.

The silane exposure 303 may simply continue for a duration empirically observed to seal all the defects on the type of structure being treated, and then be finished 306. Alternatively, the presence of silanol bonds on the surface may be monitored 304 during the process. For example, some process chambers accommodate infrared absorbance spectroscopy, and the hydroxyl groups associated with silanol bonds have peaks at 3747 cm⁻¹, 3680 cm⁻¹ and 3535 cm⁻¹. When the strengths of those peaks fall below a level predetermined as acceptable, representing a sufficient degree of removal of the HF trapped by silanol bonds, the process can be finished 306. Until that occurs, the exposure can be continued 303.

Optionally, another rinse may be done to remove any remaining HF after the defect-sealing is finished.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method of mitigating defects on a dielectric surface, comprising:
rinsing the dielectric surface; and
applying a silane composition to the dielectric surface;
wherein the defects comprise hydrogen bonds on the dielectric surface; and
wherein applying the silane composition reduces a number of the hydrogen bonds.

2. The method of claim 1, wherein at least some of the hydrogen bonds are silanol bonds.

3. The method of claim 1, wherein at least some of the hydrogen bonds are replaced by silicon bonds.

4. The method of claim 1, wherein the silane composition is applied as a liquid or a gas.

5. The method of claim 1, wherein the silane composition is applied by a technique comprising chemical vapor deposition, atomic layer deposition, or spin-coating.

6. The method of claim 1, wherein the silane composition comprises a polymer or a polymer precursor.

7. The method of claim 1, wherein a solvent in the silane composition comprises ethylene glycol, propylene carbonate, or dimethyl sulfoxide.

8. The method of claim 1, wherein the silane composition comprises 1,1,3,3-tetraethoxyl-1,3-dimethyl disiloxane or tetraethoxysilane.

9. The method of claim 1, wherein the silane composition comprises an organic solvent or an aqueous solution.

10. The method of claim 1, wherein the dielectric surface or a nearby structure is hygroscopic and the silane composition does not include water.

11. The method of claim 1, wherein the silane composition comprises a cyclic azasilane, an amine functional silane, or a silane with an amine catalyst.

12. The method of claim 1, wherein the silane composition comprises disilane (Si2H6), trisilane (Si₃H₈), neopentasilane (Si₅H₁₂, “NPS”), dichlorosilane (SiCl₂H₂, “DCS”), tris(dimethylamino)silane (C₆H₁₉N₃Si), or 2,4,6,8-tetramethylcyclotetrasiloxane (C₄H₁₆O₄Si₄).

13. The method of claim 1, wherein the silane composition is applied at an ambient pressure between about 5 Torr and about 1 atmosphere.

14. The method of claim 1, wherein the silane composition is applied at a temperature of about 100 C.

15. The method of claim 1, further comprising heating the dielectric surface as the silane composition is applied.

16. The method of claim 1, wherein the dielectric surface is rinsed with a solution comprising deionized water.

17. The method of claim 1, wherein silane in the silane composition reacts with the dielectric surface only at sites of the hydrogen bonds.

18. The method of claim 1, further comprising:
monitoring the number of the hydrogen bonds as the silane composition is applied; and
ceasing
the applying of the silane composition when the number of the hydrogen bonds falls below a predetermined level.

19. The method of claim 18, wherein the monitoring comprises measuring an infrared absorbance peak associated with the hydrogen bonds.

20. A thin-film stack, comprising:
a dielectric layer;
a metal layer formed over the dielectric layer and removed from a portion of the dielectric layer;
a defect on the portion of the dielectric layer; and
an additional silicon atom attached to the defect.
